(19) United States
(12) Patent Application Publication
(10) Pub. No.: US 2026/0032932 A1
(43) Pub. Date: Jan. 29, 2026

(54) METAL-INSULATOR-METAL CAPACITOR STRUCTURE WITH REDUCED LATERAL AREA

(71) Applicant: International Business Machines Corporation, Armonk, NY (US)

(72) Inventors: Minhaz Abedin, Delmar, NY (US); Yann Mignot, Slingerlands, NY (US); Lili Cheng, Rexford, NY (US); Lawrence Alfred Clevenger, Saratoga Springs, NY (US)

(21) Appl. No.: 18/782,096

(22) Filed: Jul. 24, 2024

(51) Int. Cl. H01L 23/522; H01L 23/528

(52) U.S. Cl. CPC H10D 1/043; H01L 23/5223; H01L 23/5226; H01L 23/5283; H10D 1/696; H10D 1/714; H10D 1/716

(57) ABSTRACT

A metal-insulator-metal capacitor (MIMCAP) structure of a semiconductor device is provided. The MIMCAP structure includes a substrate, first and second contacts formed at opposite sides of the substrate to define a MIMCAP region between the first and second contacts, vertical mandrels extending vertically upwardly from an uppermost surface of the substrate within the MIMCAP region and a MIMCAP. The MIMCAP is disposed in operable contact with the first and second contacts, on exposed sections of the uppermost surface of the substrate and over and around the vertical mandrels within the MIMCAP region. The MIMCAP includes horizontal sections between and over the vertical mandrels and outside outermost ones of the vertical mandrels and vertical sections along respective sidewalls of each of the vertical mandrels.

### BACKGROUND

The present disclosure generally relates to fabrication methods and resulting structures for semiconductor devices. More specifically, the present disclosure relates to semiconductor devices with metal-insulator-metal capacitor structures with reduced lateral area.

A capacitor is a passive two-terminal electrical component that stores electrical energy in an electric field. A capacitor is a component designed to add capacitance to a circuit. Capacitors are widely used in electronic circuits for blocking direct current while allowing alternating current to pass.

Metal-insulator-metal capacitors (MIMCAPs) are one type of capacitor design that is valuable in many applications. For example, MIMCAPs can be used in radio frequency (RF) circuits, in various configurations in analog integrated circuits (ICs), and for decoupling capacitance in high power microprocessor units (MPUs). MIMCAPs are also useful in dynamic access random memory (DRAM) cells. MIMCAPs include two metal plates (or electrodes) separated by an insulator material. Typically, the MIMCAPs are formed in one of the interconnect levels of a BEOL structure.

### SUMMARY

According to an aspect of the disclosure, a metal-insulator-metal capacitor (MIMCAP) structure of a semiconductor device is provided. The MIMCAP structure includes a substrate, first and second contacts formed at opposite sides of the substrate to define a MIMCAP region between the first and second contacts, vertical mandrels extending vertically upwardly from an uppermost surface of the substrate within the MIMCAP region and a MIMCAP. The MIMCAP is disposed in operable contact with the first and second contacts, on exposed sections of the uppermost surface of the substrate and over and around the vertical mandrels within the MIMCAP region. The MIMCAP includes horizontal sections between and over the vertical mandrels and outside outermost ones of the vertical mandrels and vertical sections along respective sidewalls of each of the vertical mandrels. In one or more additional or alternative embodiments, the MIMCAP structure of the semiconductor device provides for a MIMCAP with a reduced lateral area that provides a same capacitance as one with a larger lateral area.

According to an aspect of the disclosure, a metal-insulator-metal capacitor (MIMCAP) structure of a semiconductor device is provided. The MIMCAP structure includes a substrate including a metallization layer, a dielectric cap layer disposed on the metallization layer, an uppermost dielectric layer and a semiconductor material layer interposed between the uppermost dielectric layer and the dielectric cap layer, a first contact, a second contact electrically connected to the metallization layer, vertical mandrels extending vertically upwardly from the uppermost dielectric layer and a MIMCAP. The MIMCAP is disposed in operable contact with the first and second contacts, on exposed sections of the uppermost dielectric layer and over and around the vertical mandrels. The MIMCAP includes horizontal sections between and over the vertical mandrels and outside outermost ones of the vertical mandrels and vertical sections along respective sidewalls of each of the vertical mandrels. In one or more additional or alternative embodiments, the MIMCAP structure of the semiconductor device provides for a MIMCAP with a reduced lateral area that provides a same capacitance as one with a larger lateral area.

According to an aspect of the disclosure, a method of fabricating a semiconductor device with a metal-insulator-metal capacitor (MIMCAP) structure is provided. The method includes arranging vertical mandrels to extend vertically upwardly from an uppermost surface of a substrate, building up a MIMCAP on exposed sections of the uppermost surface of the substrate and over and around the vertical mandrels to include horizontal sections between and over the vertical mandrels and outside outermost ones of the vertical mandrels and vertical sections along respective sidewalls of each of the vertical mandrels and forming the first and second contacts to be in operable contact with the MIMCAP. In one or more additional or alternative embodiments, the method provides for a MIMCAP with a reduced lateral area that provides a same capacitance as one with a larger lateral area.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1A is a side view of a MIMCAP structure of a semiconductor device in accordance with one or more embodiments;

FIG. 1B is a top-down view of vertical mandrels of the MIMCAP structure of FIG. 1A provided as fins in accordance with one or more embodiments;

FIG. 1C is a top-down view of vertical mandrels of the MIMCAP structure of FIG. 1A provided as pillars in accordance with one or more embodiments;

FIG. 2 is a side view of the MIMCAP structure of FIG. 1A with an uppermost dielectric layer and a dielectric cap layer in accordance with one or more embodiments;

FIG. 3 is a side view of the MIMCAP structure of FIG. 1A with a metallization layer, an uppermost dielectric layer, a dielectric cap layer on the metallization layer and a semiconductor material layer interposed between the uppermost dielectric layer and the dielectric cap layer in accordance with one or more embodiments;

FIG. 4 is a side view of the MIMCAP structure of FIG. 1A with metallic vertical mandrels and with a metallization layer, an uppermost dielectric layer, a dielectric cap layer on the metallization layer, a semiconductor material layer interposed between the uppermost dielectric layer and the dielectric cap layer and a metallic material layer on the uppermost dielectric layer in accordance with one or more embodiments;

FIG. 5 is a side view of the MIMCAP structure of FIG. 1A with a planar MIMCAP in accordance with one or more embodiments;

FIG. 6 is a side view of the MIMCAP structure of FIG. 1A with a planar MIMCAP interposed between dielectric layers in accordance with one or more embodiments;

FIG. 7 is a side view of the MIMCAP structure of FIG. 1A with a planar MIMCAP and an upper dielectric layer on the planar MIMCAP in accordance with one or more embodiments;

FIG. 8 is a side view of the MIMCAP structure of FIG. 1A with an additional contact in accordance with one or more embodiments;

FIG. 9 is a side view of a MIMCAP structure of a semiconductor device with a first contact at and along upper portions of a MIMCAP in accordance with one or more embodiments;

FIG. 10 is a flow diagram illustrating a method of fabricating a MIMCAP structure of a semiconductor device in accordance with one or more embodiments; and

FIG. 11 is a flow diagram illustrating a particular details of a method of fabricating a MIMCAP structure of a semiconductor device in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with three or four digit reference numbers. With minor exceptions, the leftmost digit(s) of each reference number correspond to the figure in which its element is first illustrated.

### DETAILED DESCRIPTION

According to an aspect of the disclosure, a metal-insulator-metal capacitor (MIMCAP) structure of a semiconductor device is provided. The MIMCAP structure includes a substrate, first and second contacts formed at opposite sides of the substrate to define a MIMCAP region between the first and second contacts, vertical mandrels extending vertically upwardly from an uppermost surface of the substrate within the MIMCAP region and a MIMCAP. The MIMCAP is disposed in operable contact with the first and second contacts, on exposed sections of the uppermost surface of the substrate and over and around the vertical mandrels within the MIMCAP region. The MIMCAP includes horizontal sections between and over the vertical mandrels and outside outermost ones of the vertical mandrels and vertical sections along respective sidewalls of each of the vertical mandrels. In one or more additional or alternative embodiments, the MIMCAP structure of the semiconductor device provides for a MIMCAP with a reduced lateral area that provides a same capacitance as one with a larger lateral area.

In accordance with one or more additional or alternative embodiments, the MIMCAP includes at least two first metal layers electrically connected to the first contact and displaced from the second contact, at least one second metal layer electrically connected to the second contact and displaced from the first contact and dielectric material, the at least two first metal layers and the at least one second metal layer being interleaved with one another and the dielectric material being interleaved with the at least two first metal layers and with the at least one second metal layer so that the MIMCAP can provide increased capacitance with reduced lateral area.

In accordance with one or more additional or alternative embodiments, the uppermost surface of the substrate includes an uppermost dielectric layer from which the vertical mandrels extend vertically upwardly and on which a lower portion of the horizontal sections of the MIMCAP are disposed to support adhesion.

In accordance with one or more additional or alternative embodiments, the substrate includes one or more layers of at least one of semiconductor material, dielectric material and metallic material and the one or more layers include a dielectric cap layer to support adhesion and to make the MIMCAP structure applicable to various types of semiconductor device configurations.

In accordance with one or more additional or alternative embodiments, the substrate includes one or more layers of at least one of semiconductor material, dielectric material and metallic material and the one or more layers include a metallization layer to which the first and second contacts are electrically connected, a dielectric cap layer disposed on the metallization layer, an uppermost dielectric layer forming the uppermost surface of the substrate and from which the vertical mandrels extend vertically upwardly and on which a lower portion of the horizontal sections of the MIMCAP are disposed and a semiconductor material layer interposed between the uppermost dielectric layer and the dielectric cap layer to support adhesion and to minimize capacitance between the MIMCAP and the metallization layer.

In accordance with one or more additional or alternative embodiments, the vertical mandrels are metallic and the one or more layers further include a metallic material layer disposed on the uppermost dielectric layer and from which the vertical mandrels extend vertically upwardly to support adhesion and to minimize capacitance between the MIMCAP and the metallization layer.

In accordance with one or more additional or alternative embodiments, the substrate includes one or more layers of at least one of semiconductor material, dielectric material and metallic material and the one or more layers include a metallization layer to which the first and second contacts are electrically connected, a dielectric cap layer disposed on the metallization layer, a planar MIMCAP forming the uppermost surface of the substrate and from which the vertical mandrels extend vertically upwardly and on which a lower portion of the horizontal sections of the MIMCAP are disposed and a semiconductor material layer interposed between the planar MIMCAP and the dielectric cap layer to support adhesion and to minimize capacitance between the MIMCAP and the metallization layer.

In accordance with one or more additional or alternative embodiments, the one or more layers further include upper dielectric material layers and the planar MIMCAP is interposed between the upper dielectric material layers to support adhesion and to minimize capacitance between the MIMCAP and the metallization layer.

In accordance with one or more additional or alternative embodiments, the one or more layers further include an upper dielectric material layer and the planar MIMCAP underlies the upper dielectric material layer to support adhesion and to minimize capacitance between the MIMCAP and the metallization layer.

In accordance with one or more additional or alternative embodiments, an additional contact is disposed in contact with a horizontal section of the MIMCAP disposed over at least a middle one of the vertical mandrels to provide an additional via landing.

According to an aspect of the disclosure, a metal-insulator-metal capacitor (MIMCAP) structure of a semiconductor device is provided. The MIMCAP structure includes a substrate including a metallization layer, a dielectric cap layer disposed on the metallization layer, an uppermost dielectric layer and a semiconductor material layer interposed between the uppermost dielectric layer and the dielectric cap layer, a first contact, a second contact electrically connected to the metallization layer, vertical mandrels extending vertically upwardly from the uppermost dielectric layer and a MIMCAP. The MIMCAP is disposed in operable contact with the first and second contacts, on exposed sections of the uppermost dielectric layer and over and around the vertical mandrels. The MIMCAP includes horizontal sections between and over the vertical mandrels and outside outermost ones of the vertical mandrels and vertical sections along respective sidewalls of each of the vertical mandrels. In one or more additional or alternative embodiments, the MIMCAP structure of the semiconductor device provides for a MIMCAP with a reduced lateral area that provides a same capacitance as one with a larger lateral area.

According to an aspect of the disclosure, a method of fabricating a semiconductor device with a metal-insulator-metal capacitor (MIMCAP) structure is provided. The method includes arranging vertical mandrels to extend vertically upwardly from an uppermost surface of a substrate, building up a MIMCAP on exposed sections of the uppermost surface of the substrate and over and around the vertical mandrels to include horizontal sections between and over the vertical mandrels and outside outermost ones of the vertical mandrels and vertical sections along respective sidewalls of each of the vertical mandrels and forming the first and second contacts to be in operable contact with the MIMCAP. In one or more additional or alternative embodiments, the method provides for a MIMCAP with a reduced lateral area that provides a same capacitance as one with a larger lateral area.

In accordance with one or more additional or alternative embodiments, the building up of the MIMCAP includes laying down at least two first metal layers in electrical connection with the first contact and displaced from the second contact, laying down at least one second metal layer in electrical connection with the second contact and displaced from the first contact, interleaving the at least two first metal layers with the at least one second metal layer and interleaving dielectric material with the at least two first metal layers and with the at least one second metal layer so that the MIMCAP can provide increased capacitance with reduced lateral area.

In accordance with one or more additional or alternative embodiments, the uppermost surface of the substrate includes an uppermost dielectric layer from which the vertical mandrels extend vertically upwardly and on which a lower portion of the horizontal sections of the MIMCAP are disposed to support adhesion.

In accordance with one or more additional or alternative embodiments, the substrate includes one or more layers of at least one of semiconductor material, dielectric material and metallic material and the one or more layers comprise a dielectric cap layer to support adhesion and to make the MIMCAP structure applicable to various types of semiconductor device configurations.

In accordance with one or more additional or alternative embodiments, the substrate includes one or more layers of at least one of semiconductor material, dielectric material and metallic material and the one or more layers include a metallization layer to which the first and second contacts are electrically connected, a dielectric cap layer disposed on the metallization layer, an uppermost dielectric layer forming the uppermost surface of the substrate and from which the vertical mandrels extend vertically upwardly and on which a lower portion of the horizontal sections of the MIMCAP are disposed and a semiconductor material layer interposed between the uppermost dielectric layer and the dielectric cap layer to support adhesion and to minimize capacitance between the MIMCAP and the metallization layer.

In accordance with one or more additional or alternative embodiments, the vertical mandrels are metallic and the one or more layers further include a metallic material layer disposed on the uppermost dielectric layer and from which the vertical mandrels extend vertically upwardly to support adhesion and to minimize capacitance between the MIMCAP and the metallization layer.

In accordance with one or more additional or alternative embodiments, the substrate includes one or more layers of at least one of semiconductor material, dielectric material and metallic material and the one or more layers include a metallization layer to which the first and second contacts are electrically connected, a dielectric cap layer disposed on the metallization layer, a planar MIMCAP forming the uppermost surface of the substrate and from which the vertical mandrels extend vertically upwardly and on which a lower portion of the horizontal sections of the MIMCAP are disposed and a semiconductor material layer interposed between the planar MIMCAP and the dielectric cap layer, wherein the one or more layers further include upper dielectric material layers and the planar MIMCAP is interposed between the upper dielectric material layers to support adhesion and to minimize capacitance between the MIMCAP and the metallization layer.

In accordance with one or more additional or alternative embodiments, the substrate includes one or more layers of at least one of semiconductor material, dielectric material and metallic material and the one or more layers include a metallization layer to which the first and second contacts are electrically connected, a dielectric cap layer disposed on the metallization layer, a planar MIMCAP forming the uppermost surface of the substrate and from which the vertical mandrels extend vertically upwardly and on which a lower portion of the horizontal sections of the MIMCAP are disposed and a semiconductor material layer interposed between the planar MIMCAP and the dielectric cap layer, wherein the one or more layers further include an upper dielectric material layer and the planar MIMCAP underlies the upper dielectric material layer to support adhesion and to minimize capacitance between the MIMCAP and the metallization layer.

In accordance with one or more additional or alternative embodiments, the method further includes disposing an additional contact in contact with a horizontal section of the MIMCAP disposed over at least a middle one of the vertical mandrels to provide an additional via landing.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage or the BEOL stage. Generally, the FEOL stage is where device elements (e.g., transistors, etc.) are patterned in a semiconductor substrate/wafer. The FEOL stage processes include wafer preparation, isolation, gate patterning and the formation of wells, source/drain (S/D) regions, extension junctions, silicide regions and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections. The various BEOL layers are interconnected by vias that couple from one layer to another. In a multilayered interconnect structure, the metallization layers (lines) are referred to as “M” layers (e.g., M1 layer, M2 layer, etc.) while “V” layers denote the conductive vias placed between adjacent M layers (e.g., V1 is between the M1 and M2 layers).

In semiconductor devices, MIMCAPs are used to prevent disruptions in power from disrupting chip operations. The capacitance, C, of a MIMCAP is equal to a permittivity, E, of a dielectric (absolute, not relative) multiplied by an area, A, of plate overlap in square meters and divided by a distance, D, between the plates in meters. There is therefore a continuing need for MIMCAPs in which each layer has a relatively large surface area and a uniform thickness. This has been achieved previously by forming an opening in a surface of a first insulating layer, forming a lower metal layer on the surface of the first insulating layer with sidewalls and a bottom surface of the opening, where the sidewalls are tapered inwardly from the surface of the first insulating layer to the bottom surface of the opening by a taper angle of between 10 degrees and 45 degrees. Such prior structures still take up a significant amount of surface area of a semiconductor device.

Turning now to an overview of the aspects of the disclosure, one or more embodiments of the disclosure address the above-described shortcomings of the prior art by providing a MIMCAP structure of a semiconductor device. The MIMCAP structure includes a substrate, first and second contacts formed at opposite sides of the substrate to define a MIMCAP region between the first and second contacts, vertical mandrels extending vertically upwardly from an uppermost surface of the substrate within the MIMCAP region and a MIMCAP disposed in operable contact with the first and second contacts, on exposed sections of the uppermost surface of the substrate and over and around the vertical mandrels within the MIMCAP region. The MIMCAP includes horizontal sections between and over the vertical mandrels and outside outermost ones of the vertical mandrels and vertical sections along respective sidewalls of each of the vertical mandrels.

The above-described aspects of the disclosure address the shortcomings of the prior art by providing a semiconductor device that includes a MIMCAP structure with a reduced lateral area. The MIMCAP structure includes a mandrel fabricated prior to MIMCAP layer deposition, vertical structures on top of a bottom metal line dielectric cap, which is leveraged for adhesion, an additional dielectric cap over a MIMCAP structure as well as on the top and the bottom metal line and, in some cases, additional cap material on top of an already existing metal dielectric cap.

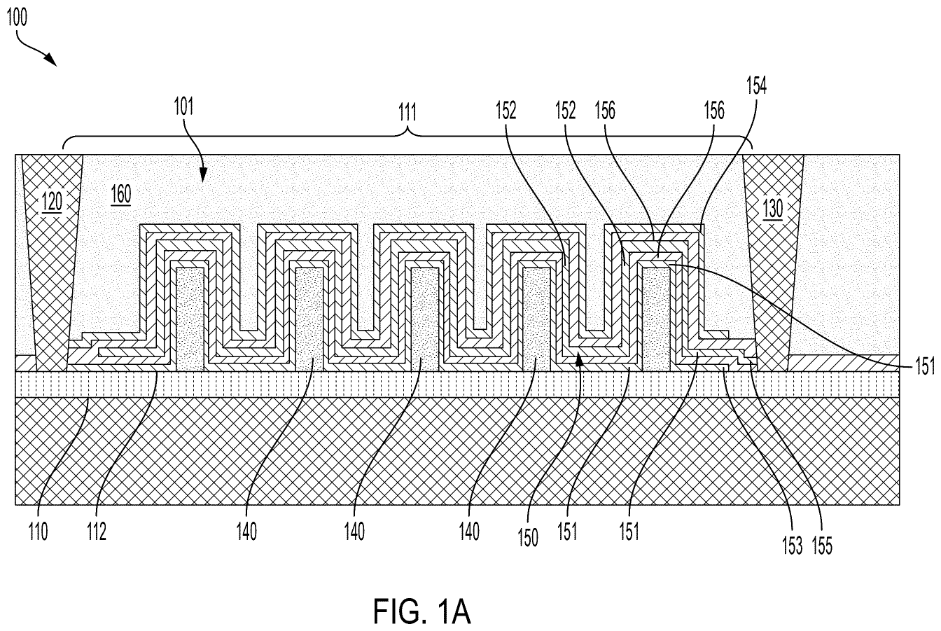

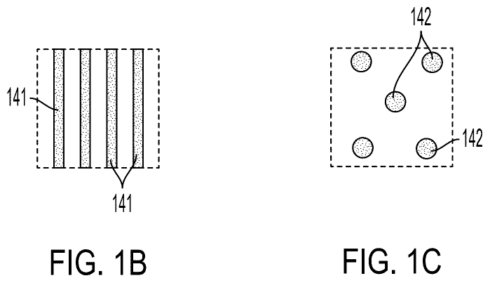

With reference to FIGS. 1A, 1B and 1C, a MIMCAP structure 101 of a semiconductor device 100 is provided. The MIMCAP structure 101 includes a substrate 110, a first contact 120, a second contact 130, vertical mandrels 140 and a MIMCAP 150. The first contact 120 and the second contact 130 are formed at opposite sides of the substrate 110 to define a MIMCAP region 111 between the first contact 120 and the second contact 130. The vertical mandrels 140 extend vertically upwardly from an uppermost surface 112 of the substrate 110 within the MIMCAP region 111 as at least one or more of fins 141 (see FIG. 1A) and pillars 142 (see FIG. 1). The MIMCAP 150 is disposed in operable contact with the first contact 120 and with the second contact 130. The MIMCAP 150 is disposed on exposed sections of the uppermost surface 112 of the substrate 110 and is disposed over and around each of the vertical mandrels 140 within the MIMCAP region 111. The MIMCAP 150 includes horizontal sections 151 and vertical sections 152. The horizontal sections 151 extend horizontally between and over the vertical mandrels 140 and outside outermost ones of the vertical mandrels 140 to the first contact 120 and to the second contact 130. The vertical sections 152 extend vertically upwardly and vertically downwardly along respective sidewalls of each of the vertical mandrels 140. The MIMCAP structure 101 can further include interlayer dielectric (ILD) 160 over and around the first contact 120, the second contact 130 and the MIMCAP 150.

A width of the substrate 110 can exceed a width of the MIMCAP region 111 and the substrate 110 can include one or more layers of various semiconductor materials, dielectric materials and/or metallic materials as described below. The first contact 120 and the second contact 130 can terminate at the uppermost surface 112 of the substrate 110 or can penetrate through the uppermost surface 112 of the substrate 110 to underlying layers of the substrate 110. Also, as described below, the vertical mandrels 140 can be formed of a single material, such as amorphous silicon, silicon, ILD, etc.

In accordance with one or more embodiments, angles formed between the horizontal sections 151 and the vertical sections 152 can be up to 90 degrees. That is, each of the vertical sections 152 of the MIMCAP 150 can form right angles with proximal ones of the horizontal sections 151 of the MIMCAP 150.

To achieve capacitance, the MIMCAP 150 includes at least two first metal layers 153 and 154 that are each electrically connected to the first contact 120 and that are each electrically displaced from the second contact 130, at least one second metal layer 155 that is electrically connected to the second contact 130 and that is electrically displaced from the first contact 120, and dielectric material 156. The at least two first metal layers 153 and 154 and the at least one second metal layer 155 are interleaved with one another. The dielectric material 156 is interleaved with the at least two first metal layers 153 and 154 and is interleaved with the at least one second metal layer 155. It is to be understood that numbers of the at least two first metal layers 153 and 154 and that numbers of the at least one second metal layer 155 can be increased to correspondingly increase capacitance to an extent space is available and in, for example, manners that are consistent with lithographic processes and other similar processes.

With the configuration of FIGS. 1A, 1B and 1C as described above and in the following description, with the angles formed between the horizontal sections 151 and the vertical sections 152 being up to 90 degrees, the vertical sections 152 of the MIMCAP 150 increase an area for capacitance and, hence, less total lateral area is required for the MIMCAP structure 101 to achieve a same level of capacitance. In addition, the overall structure including the vertical mandrels 140 minimizes coupling to signal lines above and below the MIMCAP 150.

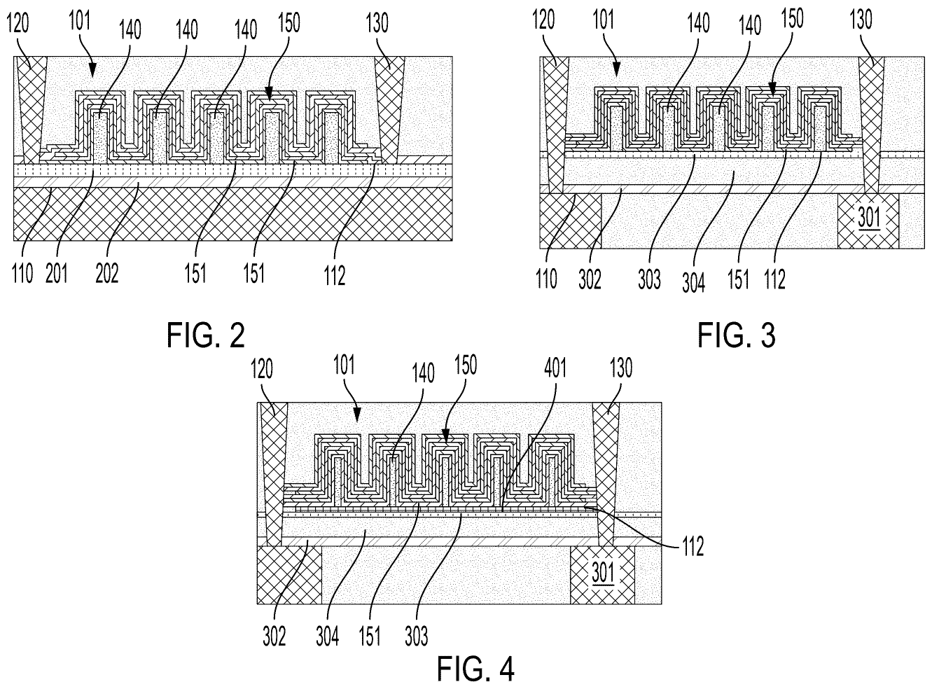

With continued reference to FIG. 1A and with additional reference to FIGS. 2-7, the uppermost surface 112 of the substrate 110 can include or be provided as an uppermost dielectric layer 201 (see FIG. 2), such as a nitride film to support adhesion of at least one of the vertical mandrels 140 and the horizontal sections 151 of the MIMCAP 150. The vertical mandrels 140 can extend vertically upwardly from the uppermost dielectric layer 201 and lower portions of the horizontal sections 151 of the MIMCAP 150 can be disposed on the uppermost dielectric layer 201 (i.e., upper portions of the horizontal sections 151 are disposed over the upper ends of the vertical mandrels 140). In accordance with one or more embodiments, the substrate 110 can include one or more layers of at least one of semiconductor material, dielectric material and metallic material and, in these or other cases, the one or more layers can include a dielectric cap layer 202 (see FIG. 2) that underlies the uppermost dielectric layer 201.

As shown in FIG. 3, the one or more layers of the substrate 110 can include a metallization layer 301 (i.e., an M(x-1) signal line layer) to which the first contact 120 and the second contact 130 are electrically connected, a dielectric cap layer 302 disposed on the metallization layer 301, an uppermost dielectric layer 303 forming the uppermost surface 112 of the substrate 110 and from which the vertical mandrels 140 extend vertically upwardly and on which lower portions of the horizontal sections 151 of the MIMCAP 150 are disposed and a semiconductor material layer 304 that is interposed between the uppermost dielectric layer 303 and the dielectric cap layer 302. In these or other cases, the first contact 120 and the second contact 130 penetrate through the uppermost dielectric layer 303, the semiconductor material layer 304 and the dielectric cap layer 302 to terminate at the metallization layer 301. A benefit of the configuration of FIG. 3 and other similar configurations is minimization of capacitance between the MIMCAP 150 and the metallization layer 301.

In accordance with one or more embodiments and as shown in FIG. 4, the vertical mandrels 140 can be formed of metallic materials and the one or more layers of the substrate 110 can further include a metallic material layer 401 disposed on the uppermost dielectric layer 303 of FIG. 3 and from which the vertical mandrels 140 extend vertically upwardly and on which lower portions of the horizontal sections 151 of the MIMCAP 150 are disposed.

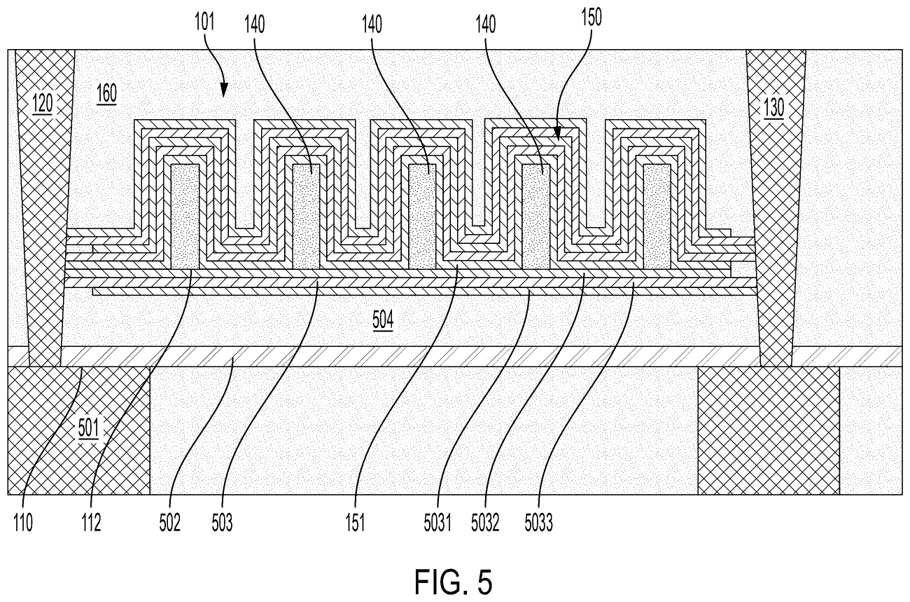

As shown in FIG. 5, the one or more layers of the substrate 110 can include a metallization layer 501 (i.e., an M(x-1) signal line layer) to which the first contact 120 and the second contact 130 are electrically connected, a dielectric cap layer 502 disposed on the metallization layer 501, a planar MIMCAP 503 forming the uppermost surface 112 of the substrate 110 and from which the vertical mandrels 140 extend vertically upwardly and on which lower portions of the horizontal sections 151 of the MIMCAP 150 are disposed and a semiconductor material layer 504 that is interposed between the planar MIMCAP 503 and the dielectric cap layer 502. The planar MIMCAP 503 can include at least first and second planar metal layers 5031 and 5032 and at least a planar dielectric layer 5033 interposed between the at least first and second planar metal layers 5031 and 5032. It is to be understood that numbers of the at least first and second planar metal layers 5031 and 5032 and that numbers of the at least the planar dielectric layer 5033 can be increased to correspondingly increase capacitance of the planar MIMCAP 503 to an extent space is available and in, for example, manners that are consistent with lithographic processes and other similar processes.

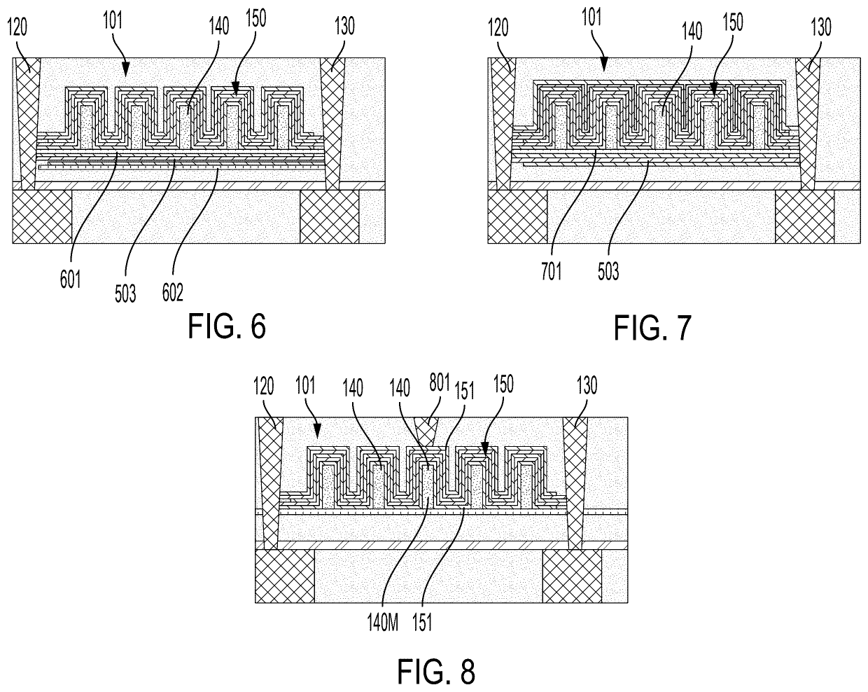

As shown in FIGS. 6 and 7, the substrate 110 can further include upper dielectric material layers 601 and 602 and the planar MIMCAP 503 of FIG. 3 can be interposed between the upper dielectric material layers 601 and 602 (see FIG. 6) and/or the substrate 110 can further include an upper dielectric material layer 701 and the planar MIMCAP 503 of FIG. 5 can underly the upper dielectric material layer 701 (see FIG. 7).

With reference to FIG. 8, the MIMCAP structure 101 can further include an additional contact 801 that is disposed in contact with a horizontal section 151 of the MIMCAP 150, which is disposed over at least a middle one 140M of the vertical mandrels 140.

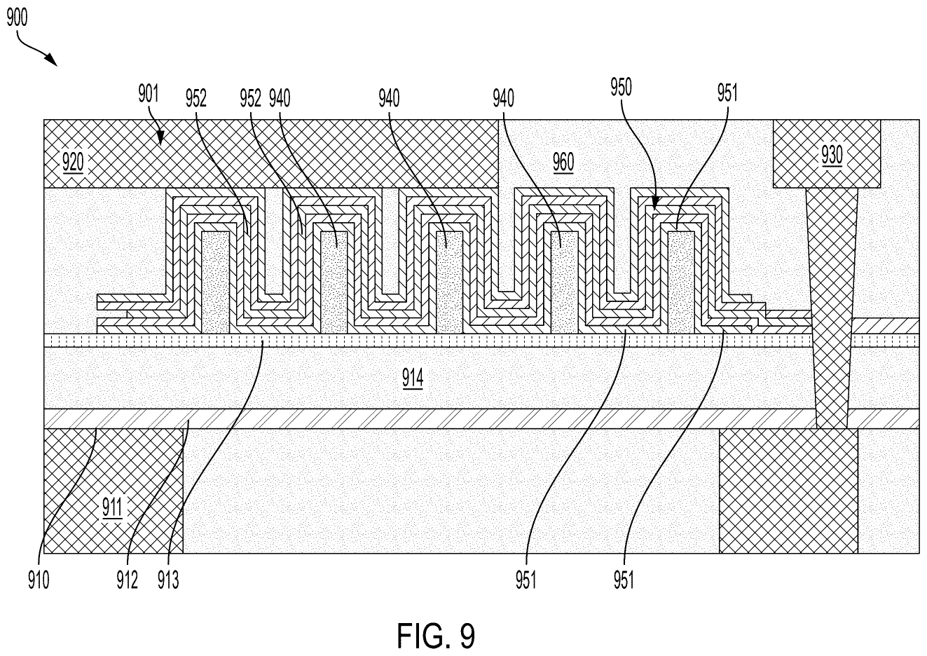

With reference to FIG. 9, a MIMCAP structure 901 of a semiconductor device 900 is provided and is generally similar to the MIMCAP structure 101 of FIG. 1A except as described below. The MIMCAP structure 901 includes a substrate 910 and the substrate 910 includes a metallization layer 911 (i.e., an M(x-1) signal line layer), a dielectric cap layer 912 disposed on the metallization layer 911, an uppermost dielectric layer 913 and a semiconductor material layer 914 interposed between the uppermost dielectric layer 913 and the dielectric cap layer 912. The MIMCAP structure 901 further includes a first contact 920, a second contact 930 electrically connected to the metallization layer 911, vertical mandrels 940 extending vertically upwardly from the uppermost dielectric layer 913 and a MIMCAP 950. The vertical mandrels 940 can be provided as at least one or more of fins as shown in FIG. 1B and as pillars as shown in FIG. 1C. The MIMCAP 950 is disposed in operable contact with the first contact 920 and with the second contact 930. The MIMCAP 950 is disposed on exposed sections of the uppermost dielectric layer 913 and is disposed over and around each of the vertical mandrels 940. The MIMCAP 950 includes horizontal sections 951 and vertical sections 952. The horizontal sections 951 extend horizontally between and over the vertical mandrels 940 and outside outermost ones of the vertical mandrels 940 to at least the second contact 930. The vertical sections 952 extend vertically upwardly and vertically downwardly along respective sidewalls of each of the vertical mandrels 940. The MIMCAP structure 901 can further include interlayer dielectric (ILD) 960 over and around the first contact 920, the second contact 930 and the MIMCAP 950. In accordance with one or more embodiments, the first contact 920 is disposed at and along a top of the MIMCAP structure 901 and contacts at least upper portions of the horizontal sections 951 of the MIMCAP 950.

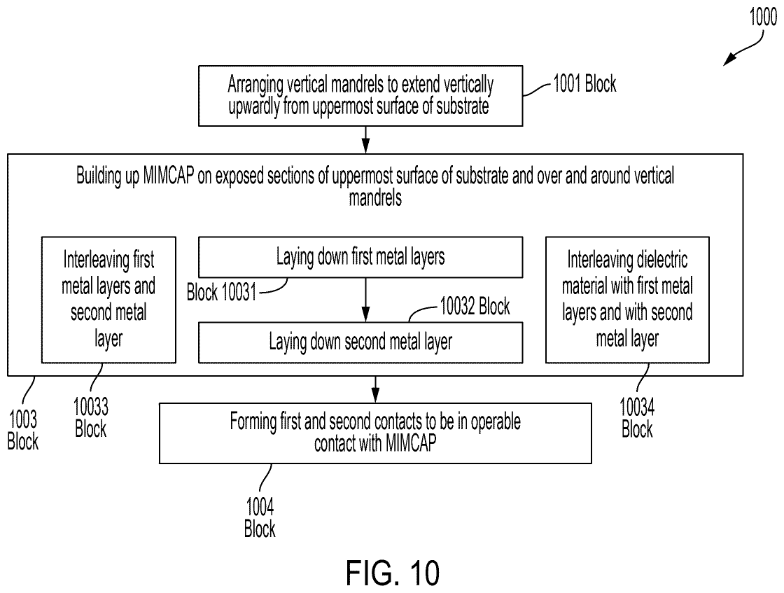

With reference to FIG. 10, a method 1000 of fabricating a semiconductor device with a MIMCAP structure, such as the MIMCAP structure 101 and the MIMCAP structure 901 described above, is provided. The method 1000 includes arranging vertical mandrels to extend vertically upwardly from an uppermost surface of a substrate (block 1001), building up a MIMCAP on exposed sections of the uppermost surface of the substrate and over and around the vertical mandrels (block 1003) such that the MIMCAP includes horizontal sections between and over the vertical mandrels and outside outermost ones of the vertical mandrels and vertical sections along respective sidewalls of each of the vertical mandrels and forming the first and second contacts to be in operable contact with the MIMCAP (block 1004). In accordance with one or more embodiments, the building up of the MIMCAP of block 1003 can include laying down at least two first metal layers in electrical connection with the first contact and displaced from the second contact (block 10031), laying down at least one second metal layer in electrical connection with the second contact and displaced from the first contact (block 10032) and parallel operations of interleaving the at least two first metal layers with the at least one second metal layer (block 10033) and interleaving dielectric material with the at least two first metal layers and with the at least one second metal layer (block 10034).

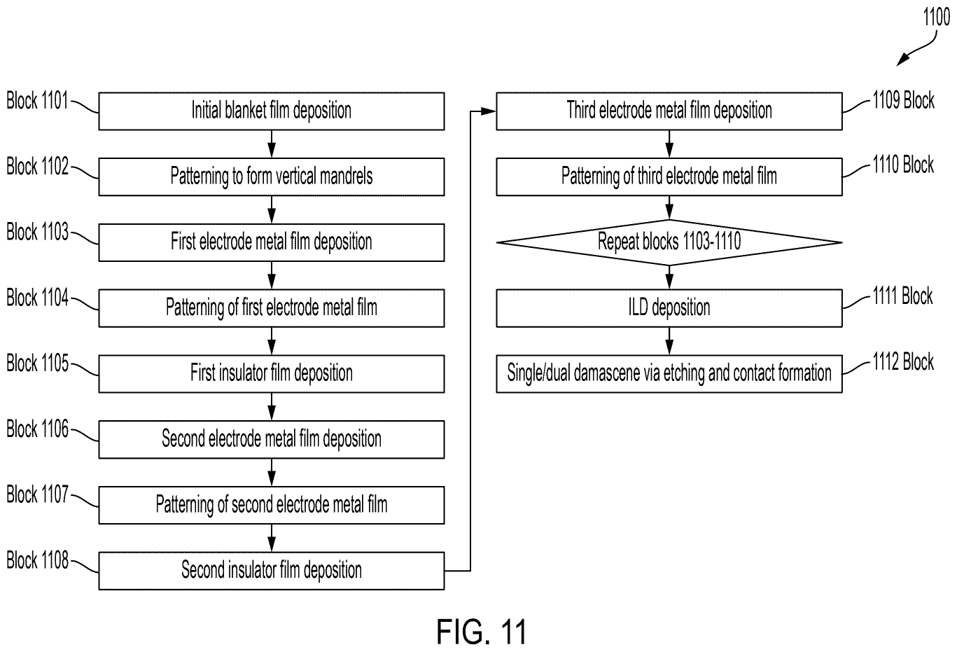

With continued reference to FIG. 10 and with additional reference to FIG. 11, the method 1000 of FIG. 10 will now be described with more particularity as a method 1100. As shown in FIG. 11, the method 1100 includes deposition of an initial blanket film of, for example, nitride, amorphous silicon, etc. (block 1101). The method 1100 then includes a patterning operation to pattern the vertical mandrels (block 1102), first electrode metal film deposition (block 1103) and patterning (block 1104), deposition of a first insulator film, such as a high-k insulator film (block 1105), second electrode metal film deposition (block 1106) and patterning (block 1107), deposition of a second insulator film, such as a high-k insulator film (block 1108) and third electrode metal film deposition (block 1109) and patterning (block 1110). The operations of blocks 1103 through 1110 can be repeated as needed and as possible. Subsequently, the method 1100 includes ILD deposition (block 1111) and single/dual damascene via etching and contact formation to connect MIMCAP terminals (block 1112).

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100}orientated crystalline surface can take on a {100}orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A metal-insulator-metal capacitor (MIMCAP) structure of a semiconductor device, the MIMCAP structure comprising:
a substrate;
first and second contacts formed at opposite sides of the substrate to define a MIMCAP region between the first and second contacts;
vertical mandrels extending vertically upwardly from an uppermost surface of the substrate within the MIMCAP region; and
a MIMCAP disposed in operable contact with the first and second contacts, on exposed sections of the uppermost surface of the substrate and over and around the vertical mandrels within the MIMCAP region,
the MIMCAP comprising:
horizontal sections between and over the vertical mandrels and outside outermost ones of the vertical mandrels; and
vertical sections along respective sidewalls of each of the vertical mandrels.

2. The MIMCAP structure according to claim 1, wherein the MIMCAP comprises:
at least two first metal layers electrically connected to the first contact and displaced from the second contact;
at least one second metal layer electrically connected to the second contact and displaced from the first contact; and
dielectric material,
the at least two first metal layers and the at least one second metal layer being interleaved with one another, and
the dielectric material being interleaved with the at least two first metal layers and with the at least one second metal layer.

3. The MIMCAP structure according to claim 1, wherein the uppermost surface of the substrate comprises an uppermost dielectric layer from which the vertical mandrels extend vertically upwardly and on which a lower portion of the horizontal sections of the MIMCAP are disposed.

4. The MIMCAP structure according to claim 1, wherein the substrate comprises one or more layers of at least one of semiconductor material, dielectric material and metallic material and the one or more layers comprise a dielectric cap layer.

5. The MIMCAP structure according to claim 1, wherein the substrate comprises one or more layers of at least one of semiconductor material, dielectric material and metallic material and the one or more layers comprise:
a metallization layer to which the first and second contacts are electrically connected;
a dielectric cap layer disposed on the metallization layer;
an uppermost dielectric layer forming the uppermost surface of the substrate and from which the vertical mandrels extend vertically upwardly and on which a lower portion of the horizontal sections of the MIMCAP are disposed; and
a semiconductor material layer interposed between the uppermost dielectric layer and the dielectric cap layer.

6. The MIMCAP structure according to claim 5, wherein the vertical mandrels are metallic and the one or more layers further comprise a metallic material layer disposed on the uppermost dielectric layer and from which the vertical mandrels extend vertically upwardly.

7. The MIMCAP structure according to claim 1, wherein the substrate comprises one or more layers of at least one of semiconductor material, dielectric material and metallic material and the one or more layers comprise:
a metallization layer to which the first and second contacts are electrically connected;
a dielectric cap layer disposed on the metallization layer;
a planar MIMCAP forming the uppermost surface of the substrate and from which the vertical mandrels extend vertically upwardly and on which a lower portion of the horizontal sections of the MIMCAP are disposed; and
a semiconductor material layer interposed between the planar MIMCAP and the dielectric cap layer.

8. The MIMCAP structure according to claim 7, wherein the one or more layers further comprise upper dielectric material layers and the planar MIMCAP is interposed between the upper dielectric material layers.

9. The MIMCAP structure according to claim 7, wherein the one or more layers further comprise an upper dielectric material layer and the planar MIMCAP underlies the upper dielectric material layer.

10. The MIMCAP structure according to claim 1, further comprising an additional contact disposed in contact with a horizontal section of the MIMCAP disposed over at least a middle one of the vertical mandrels.

11. A metal-insulator-metal capacitor (MIMCAP) structure of a semiconductor device, the MIMCAP structure comprising:
a substrate comprising a metallization layer, a dielectric cap layer disposed on the metallization layer, an uppermost dielectric layer and a semiconductor material layer interposed between the uppermost dielectric layer and the dielectric cap layer;
a first contact;
a second contact electrically connected to the metallization layer;
vertical mandrels extending vertically upwardly from the uppermost dielectric layer; and
a MIMCAP disposed in operable contact with the first and second contacts, on exposed sections of the uppermost dielectric layer and over and around the vertical mandrels,
the MIMCAP comprising:
horizontal sections between and over the vertical mandrels and outside outermost ones of the vertical mandrels; and
vertical sections along respective sidewalls of each of the vertical mandrels.

12. A method of fabricating a semiconductor device with a metal-insulator-metal capacitor (MIMCAP) structure, the method comprising:
arranging vertical mandrels to extend vertically upwardly from an uppermost surface of a substrate;
building up a MIMCAP on exposed sections of the uppermost surface of the substrate and over and around the vertical mandrels to comprise horizontal sections between and over the vertical mandrels and outside outermost ones of the vertical mandrels and vertical sections along respective sidewalls of each of the vertical mandrels; and
forming first and second contacts to be in operable contact with the MIMCAP.

13. The method according to claim 12, wherein the building up of the MIMCAP comprises:
laying down at least two first metal layers in electrical connection with the first contact and displaced from the second contact;
laying down at least one second metal layer in electrical connection with the second contact and displaced from the first contact;
interleaving the at least two first metal layers with the at least one second metal layer; and
interleaving dielectric material with the at least two first metal layers and with the at least one second metal layer.

14. The method according to claim 12, wherein the uppermost surface of the substrate comprises an uppermost dielectric layer from which the vertical mandrels extend vertically upwardly and on which a lower portion of the horizontal sections of the MIMCAP are disposed.

15. The method according to claim 12, wherein the substrate comprises one or more layers of at least one of semiconductor material, dielectric material and metallic material and the one or more layers comprise a dielectric cap layer.

16. The method according to claim 12, wherein the substrate comprises one or more layers of at least one of semiconductor material, dielectric material and metallic material and the one or more layers comprise:
a metallization layer to which the first and second contacts are electrically connected;
a dielectric cap layer disposed on the metallization layer;
an uppermost dielectric layer forming the uppermost surface of the substrate and from which the vertical mandrels extend vertically upwardly and on which a lower portion of the horizontal sections of the MIMCAP are disposed; and
a semiconductor material layer interposed between the uppermost dielectric layer and the dielectric cap layer.

17. The method according to claim 16, wherein the vertical mandrels are metallic and the one or more layers further comprise a metallic material layer disposed on the uppermost dielectric layer and from which the vertical mandrels extend vertically upwardly.

18. The method according to claim 12, wherein the substrate comprises one or more layers of at least one of semiconductor material, dielectric material and metallic material and the one or more layers comprise:
a metallization layer to which the first and second contacts are electrically connected;
a dielectric cap layer disposed on the metallization layer;
a planar MIMCAP forming the uppermost surface of the substrate and from which the vertical mandrels extend vertically upwardly and on which a lower portion of the horizontal sections of the MIMCAP are disposed; and
a semiconductor material layer interposed between the planar MIMCAP and the dielectric cap layer,
wherein the one or more layers further comprise upper dielectric material layers and the planar MIMCAP is interposed between the upper dielectric material layers.

19. The method according to claim 12, wherein the substrate comprises one or more layers of at least one of semiconductor material, dielectric material and metallic material and the one or more layers comprise:
a metallization layer to which the first and second contacts are electrically connected;
a dielectric cap layer disposed on the metallization layer;
a planar MIMCAP forming the uppermost surface of the substrate and from which the vertical mandrels extend vertically upwardly and on which a lower portion of the horizontal sections of the MIMCAP are disposed; and
a semiconductor material layer interposed between the planar MIMCAP and the dielectric cap layer,
wherein the one or more layers further comprise an upper dielectric material layer and the planar MIMCAP underlies the upper dielectric material layer.

20. The method according to claim 12, further comprising disposing an additional contact in contact with a horizontal section of the MIMCAP disposed over at least a middle one of the vertical mandrels.
